(19) United States
(12) Patent Application Publication
(10) Pub. No.: US 2025/0271555 A1
(43) Pub. Date: Aug. 28, 2025

(54) OPTOELECTRONIC STRUCTURE

(71) Applicant: Advanced Semiconductor Engineering, Inc., Kaohsiung (TW)

(72) Inventors: Jr-Wei LIN, Kaohsiung (TW); Mei-Ju LU, Kaohsiung (TW)

(73) Assignee: Advanced Semiconductor Engineering, Inc., Kaohsiung (TW)

(21) Appl. No.: 18/586,406

(22) Filed: Feb. 23, 2024

(51) Int. Cl. G01S 7/486; G01S 7/484

(52) U.S. Cl. CPC G01S 7/486; G01S 7/484

(57) ABSTRACT

An optoelectronic structure is provided. The optoelectronic structure includes an optical device; and a housing covering the optical device. The optical device is configured to transmit at least one optical signal to an outside of the housing in different directions.

### BACKGROUND

### 1. Field of the Disclosure

The instant disclosure relates to, amongst other things, an optoelectronic structure.

### 2. Description of Related Art

In current vehicular LiDAR (Light Detection and Ranging) systems, there are generally mechanical, solid-state, and fully solid-state types, with miniaturization primarily focused on solid-state and fully solid-state systems. Solid-state LiDAR, also known as “solid-state optical radar,” incorporates minimal moving parts. It utilizes MEMS (Micro-Electro-Mechanical Systems) mechanisms for a compact, electronic design that integrates the traditionally larger mechanical structures onto silicon-based chips through microelectronic processes. This design enables vertical one-dimensional scanning through MEMS mirrors, with the entire device achieving horizontal scanning by rotating 360 degrees. On the other hand, fully solid-state LiDAR systems employ the Optical Phased Array (OPA) approach, which consists of an array of multiple light sources. By controlling the phase timing differences of each light source's emission, a main light beam with a specific direction is synthesized. This main beam can then be controlled to scan in various directions, achieving millimeter-level radar accuracy. This advancement aligns with the future trends of LiDAR technology towards solid-state, miniaturization, and cost reduction.

However, in the design of purely solid-state LiDAR systems, an external prism design is still used to achieve scanning in different directions, indicating that there remains room for further miniaturization in LiDAR systems.

### SUMMARY

According to one example embodiment of the instant disclosure, an optoelectronic structure includes an optical module; and a housing covering the optical module. The optical module is configured to provide at least two optical signals, and wherein the at least two optical signals pass through the housing in different directions.

According to another example embodiment of the instant disclosure, an optoelectronic structure includes an optical emission module and an optical transceiver module. The optical emission module is configured to emit a first optical signal along a first path. The optical transceiver module is configured to receive the first optical signal and emit a second optical signal along a second path. The second path overlaps the first path in a first direction which is substantially perpendicular to the first path or the second path.

According to another example embodiment of the instant disclosure, an optoelectronic structure includes a housing having a first side and a second side different from the first side; and an optical module covered by the housing. The optical module is configured to emit and/or receive a light passing through the first side of the housing and configured to emit and/or receive another light passing through the second side of the housing.

In order to further understanding of the instant disclosure, the following embodiments are provided along with illustrations to facilitate appreciation of the instant disclosure; however, the appended drawings are merely provided for reference and illustration, and do not limit the scope of the instant disclosure.

### BRIEF DESCRIPTION OF THE DRAWINGS

FIG. 1A is a schematic top view of an optoelectronic structure in accordance with an embodiment of the instant disclosure.

FIG. 1B illustrates a schematic cross-sectional view along line A-A in FIG. 1A.

FIG. 2 is a schematic top view of an optoelectronic structure in accordance with an embodiment of the instant disclosure.

FIG. 3 is a schematic cross-sectional view of an optoelectronic structure in accordance with an embodiment of the instant disclosure.

FIG. 4 is a schematic cross-sectional view of an optoelectronic structure in accordance with an embodiment of the instant disclosure.

FIG. 5A, FIG. 5B, FIG. 5C, FIG. 5D, FIG. 5E, FIG. 5F, FIG. 5G, FIG. 5H, FIG. 5I, FIG. 5J and FIG. 5K illustrate one or more stages of an example of a method for manufacturing an optoelectronic structure in accordance with some embodiments of the present disclosure.

### DETAILED DESCRIPTION

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, spatially relative terms, such as “beneath,” “below,” “above,” “over,” “on,” “upper,” “lower,” “left,” “right,” “vertical,” “horizontal,” “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Present disclosure provides an innovative structure for the protective cover of optical systems, featuring openings that allows laser light signals to pass through. To achieve a broader scanning range and more accurate distance measurement, it also integrates a light guiding component, such as a prism, into the carrier equipped with the optical system. This integration facilitates scanning and distance measuring in various directions, enhancing the system's overall performance and versatility.

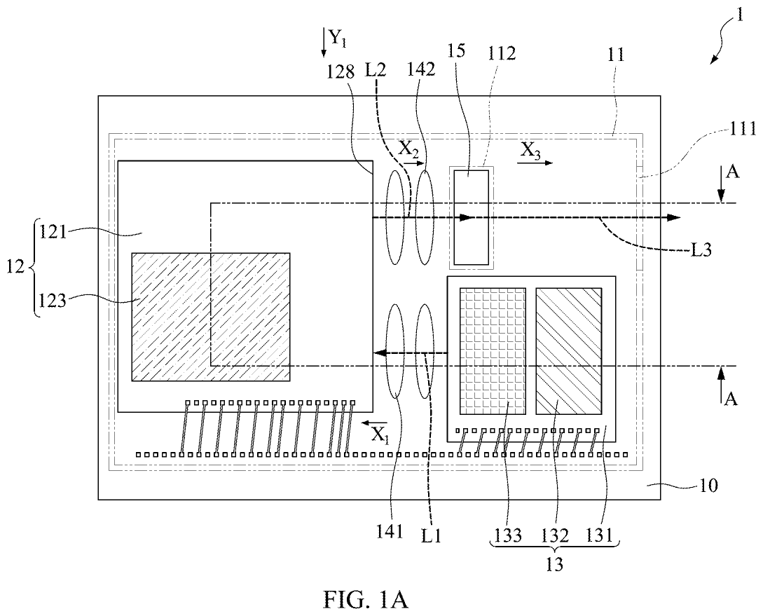

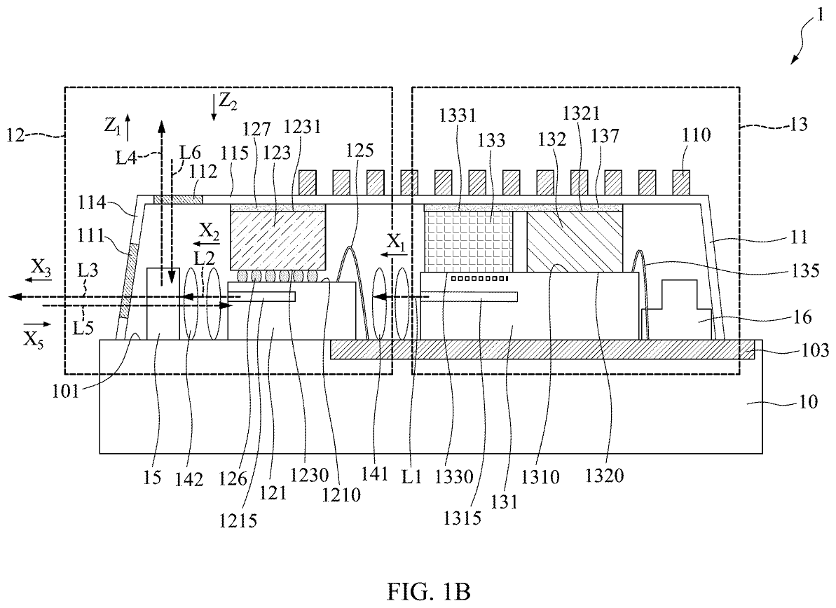

FIG. 1A is a schematic top view of an optoelectronic structure 1 in accordance with an embodiment of the instant disclosure. FIG. 1B illustrates a schematic cross-sectional view along line A-Ain FIG. 1A. As shown in FIG. 1A and FIG. 1B, the optoelectronic structure 1 may include a substrate 10, a photonic component 121, an electronic component 123, a photonic component 131, an electronic component 132 and a laser component 133. The substrate 10 may be or include a carrier. The substrate 10 may be composed of a silicon-based material, leveraging the well-established properties of silicon to enhance the device's performance and integration capabilities. Silicon-based substrates are chosen for their excellent electrical, thermal, and mechanical properties, making them ideal for a wide range of applications. The substrate 10 may include an interconnection structure, which may include such as a plurality of conductive traces and/or a plurality of conductive vias. The interconnection structure may include a redistribution layer (RDL) 103. The redistribution layer 103 may be disposed on an upper surface 101 of the substrate 10.

Referring to FIG. 1A and FIG. 1B, the photonic component 121 may be disposed over the substrate 10 and the electronic component 123 may be stacked on the photonic component 121. In some embodiments of the present disclosure, the photonic component 121 includes photonic integrated circuits (PIC). The photonic integrated circuits may be used for emitting laser pulses, guiding the optical path, and receiving the light reflected back. Moreover, the PIC of the photonic component 121 may include a waveguide 1215. The waveguide 1215 is configured to direct light waves from one point to another within the chip. By precisely controlling the shape and material properties of the waveguides, light's propagation path can be effectively managed, facilitating functions such as routing, splitting, combining, and modulating optical signals. As shown in FIG. 1i, the photonic component 121 may include a surface 1210 (e.g., an upper surface) facing away from the substrate 10. Further, the surface 1210 may include an active surface of the photonic component 121. In addition, at least one electrical connection 125 may be configured to electrically connect the active surface of the photonic component 121 to the redistribution layer 103 of the substrate 10. Thus, the photonic component 121 and the substrate 10 may be electrically connected to each other through the electrical connection 125. In some embodiments of the present disclosure, the electrical connection 125 includes a conductive wire.

In some embodiments of the present disclosure, the electronic component 123 includes electronic integrated circuits (EIC). The electronic integrated circuits may be used for processing signals from photodetectors, including signal amplification, filtering, analog-to-digital conversion (converting analog signals to digital signals), and performing initial data processing. As shown in FIG. 1B, the electronic component 123 may include a surface 1230 (e.g., a lower surface) facing the surface 1210 of the photonic component 121. Further, the surface 1230 may include an active surface of the electronic component 123. That is, the active surface of the photonic component 121 may face the active surface of the electronic component 123. Moreover, a plurality of electrical connections 126 is arranged between the surface 1210 of the photonic component 121 and the surface 1230 of the electronic component 123 and configured to electrically connect the active surface of the photonic component 121 to the active surface of the electronic component 123. Thus, the photonic component 121 and the electronic component 123 may be electrically connected to each other through the electrical connections 126. In some embodiments of the present disclosure, the electrical connection 126 includes a micro-bump.

The photonic component 121 and the electronic component 123 may jointly be considered as an optical transceiver module 12. The optical transceiver module 12 may be electrically connected to the substrate 10 through the at least one electrical connection 125.

The photonic component 131 may be disposed over the substrate 10 and the electronic component 132 and the laser component 133 may be stacked on the photonic component 131. In some embodiments of the present disclosure, the photonic component 131 includes photonic integrated circuits (PIC). The photonic integrated circuits may be used for emitting laser pulses, guiding the optical path, and receiving the light reflected back. Moreover, the PIC of the photonic component 131 may include a waveguide 1315. The waveguide 1315 is configured to direct light waves from one point to another within the chip. By precisely controlling the shape and material properties of the waveguides, light's propagation path can be effectively managed, facilitating functions such as routing, splitting, combining, and modulating optical signals. As shown in FIG. 1i, the photonic component 131 may include a surface 1310 (e.g., an upper surface) facing away from the substrate 10. Further, the surface 1310 may include an active surface of the photonic component 131. In addition, at least one electrical connection 135 may be configured to electrically connect the active surface of the photonic component 131 to the redistribution layer 103 of the substrate 10. Thus, the photonic component 131 and the substrate 10 may be electrically connected to each other through the electrical connection 135. In some embodiments of the present disclosure, the electrical connection 135 includes a conductive wire.

In some embodiments of the present disclosure, the electronic component 132 includes electronic integrated circuits (EIC). The electronic integrated circuits may be used for processing signals from photodetectors, including signal amplification, filtering, analog-to-digital conversion (converting analog signals to digital signals), and performing initial data processing. As shown in FIG. 1B, the electronic component 132 may include a surface 1320 (e.g., a lower surface) facing the surface 1310 of the photonic component 131. Further, the surface 1320 may include an active surface of the electronic component 132. That is, the active surface of the photonic component 131 may face the active surface of the electronic component 132.

The laser component 133 may include a distributed feedback laser. The distributed feedback laser may be used for emitting highly coherent and wavelength-precise light beams. As shown in FIG. 1B, the laser component 133 may include a surface 1330 (e.g., a lower surface) facing the surface 1310 of the photonic component 131. Further, the surface 1330 may include an active surface of the laser component 133. That is, the active surface of the photonic component 131 may face the active surface of the laser component 133.

Referring to FIG. 1B, the surface 1320 of the electronic component 132 and the surface 1330 of the laser component 133 may be in abutment with the surface 1310 of the photonic component 131. The photonic component 131, the electronic component 132 and the laser component 133 may be configured in a chip-to-chip assembly. The photonic component 131, the electronic component 132 and the laser component 133 may be electrically connected to each other.

The photonic component 131, the electronic component 132 and the laser component 133 may jointly be considered as an optical emission module 13. The optical emission module 13 may be electrically connected to the substrate 10 through the at least one electrical connection 135.

Moreover, since the optical transceiver module 12 may be electrically connected to the substrate 10 through the electrical connection 125 and the optical emission module 13 may be electrically connected to the substrate through the electrical connection 135, the optical transceiver module 12 and the optical emission module 13 may be electrically coupled to each other through the substrate 10.

As shown in FIG. 1A and FIG. 1B, the optoelectronic structure 1 may further include lens structures 141 and 142 and an optical guiding element 15. The lens structure 141 may be disposed between the optical transceiver module 12 and the optical emission module 13. In some embodiments of the present disclosure, the lens structure 141 includes a plurality of lenses. In some embodiments of the present disclosure, the lens structure 141 is configured to collimate the optical signal from a divergent light into a collimated or parallel light beam having a consistent beam size. Moreover, the lens structure 142 is disposed between the optical transceiver module 12 and the optical guiding element 15. In some embodiments of the present disclosure, the lens structure 142 includes a plurality of lenses. In some embodiments of the present disclosure, the lens structure 142 is configured to collimate the optical signal from a divergent light into a collimated or parallel light beam having a consistent beam size. In some embodiments of the present disclosure, the optical guiding element 15 includes a beam splitter which is used to divide an incoming light beam into two parts.

In some embodiments of the present disclosure, the optoelectronic structure 1 may further include an electronic component 16 disposed on the substrate 10. In some embodiments of the present disclosure, the electronic component 16 includes an integrated passive device (IPD).

Further, referring to FIG. 1A and FIG. 1B, the optoelectronic structure 1 may include a housing 11. The housing 11 may be disposed on the upper surface 101 of the substrate 10. The housing 11 may cover the optical transceiver module 12 (which may include the photonic component 121 and the electronic component 123), the optical emission module 13 (which may include the photonic component 131, the electronic component 132 and the laser component 133), the lens structures 141 and 142 and the optical guiding element 15. That is, the housing 11 is configured to protect the optical transceiver module 12 and the optical emission module 13. The housing 11 may include a lateral portion 114 and an upper portion 115 adjacent to the lateral portion 114. In some embodiments of the lateral portion 114 is located at a lateral side of the housing 11. That is, the lateral portion 114 of the housing 11 may be in abutment with the upper surface 101 of the substrate 10. In some embodiments of the present disclosure, the upper portion 115 is located at an upper side of the housing 11. That is, the upper portion 115 may be spaced apart from the upper surface 101 of the substrate 10. The lateral portion 114 of the housing 11 may include an opening 111. As shown in FIG. 1B, the opening 111 may be substantially aligned with the optical guiding element 15 in a direction which may be substantially parallel to the upper surface 101 of the substrate 10. The upper portion 115 of the housing 11 may include an opening 112. As shown in FIG. 1B, the opening 112 may be disposed directly above the optical guiding element 15 and substantially aligned with the optical guiding element 15 in a direction which may be substantially perpendicular to the upper surface 101 of the substrate 10.

Referring to FIG. 1B, the housing 11 may include a heat sink 110 at its upper side. In some embodiments of the present disclosure, the housing 11 may include a thermal conductive material. The electronic component 123 may be connected to the upper side of the housing 11. A surface 1231 (e.g., an upper surface) of the electronic component 123 may be attached to the upper side of the housing 11 through a thermal interface material (TIM) 127. In some embodiments of the present disclosure, the thermal interface material 127 includes a thermal paste. That is, the housing 11 with the heat sink 110 and the thermal interface material 127 may provide a thermal dissipation path for the optical transceiver module 12. Moreover, the electronic component 132 and the laser component 133 may be connected to the upper side of the housing 11. A surface 1321 (e.g., an upper surface) of the electronic component 132 and a surface 1331 (e.g., an upper surface) of the laser component 133 may be attached to the upper side of the housing 11 through a thermal interface material (TIM) 137. In some embodiments of the present disclosure, the thermal interface material 137 includes a thermal paste. That is, the housing 11 with the heat sink 110 and the thermal interface material 137 may provide a thermal dissipation path for the optical emission module 13. In addition, because the upper surfaces of the electronic component 123, the electronic component 132 and the laser component 133 may be all attached to the upper side of the housing 11, it can be understood that the upper surfaces of the electronic component 123, the electronic component 132 and the laser component 133 may be substantially coplanar with each other.

As shown in FIG. 1A and FIG. 1B, the optical emission module 13 may emit an optical signal L1 to the optical transceiver module 12 along a direction X1. In some embodiments of the present disclosure, the optical signal L1 includes at least one laser light beam. In some embodiments of the present disclosure, the waveguide 1315 of the photonic component 131 is configured to transmit the optical signal L1. The optical signal L1 emitted from the optical emission module 13 may pass through the lens structure 141. Therefore, it can be known that the path of the optical signal L1 may be substantially along the direction X1 and may pass through the lens structure 141.

The optical transceiver module 12 is configured to receive and/or detect the optical signal L1 emitted from the optical emission module 13. Then, the optical transceiver module 12 may emit an optical signal L2 to the optical guiding element 15 along a direction X2. In some embodiments of the present disclosure, the optical signal L2 includes at least one laser light beam. In some embodiments of the present disclosure, the waveguide 1215 of the photonic component 121 is configured to transmit the optical signal L2. The optical signal L2 emitted from the optical transceiver module 12 may pass through the lens structure 142. Therefore, it can be known that the path of the optical signal L2 may be substantially along the direction X2 and may pass through the lens structure 142. In some embodiments of the present disclosure, the direction X1 and the direction X2 are substantially parallel to each other. Thus, the path of the optical signal L1 may be substantially parallel to the path of the optical signal L2. Moreover, referring to FIG. 1A, the path of the optical signal L1 may overlap the path of the optical signal L2 in a direction Y1, which may be substantially perpendicular to the path of the optical signal L1 or the path of the optical signal L2. Referring to FIG. 1A, the direction X1 and the direction X2 are opposite to each other. In addition, the photonic component 121 of the optical transceiver module 12 may receive the optical signal L1 and emit the optical signal L2 at the same lateral side 128.

The optical guiding element 15 may divide the optical signal L2 emitted from the optical transceiver module 12 into two parts. That is, after the optical guiding element 15 receives the optical signal L2 emitted from the optical transceiver module 12, the optical guiding element 15 may generate an optical signal L3 along a direction X3 and an optical signal L4 along a direction Z1. The direction X3 may be substantially identical to, or parallel to the direction X2. The direction Z1 may be substantially perpendicular to the direction X3 or the direction X2. Thus, the optical guiding element 15 may split the optical signal L2, emitted by the optical transceiver module 12, into two optical signals, L3 and L4. Optical signal L3 is guided in the direction X3, which may be substantially the same as the direction X2 of optical signal L2, while optical signal L4 is directed along the direction Z1, differing from the direction X2 of optical signal L2.

The optical signal L3 generated from the optical guiding element 15 may advance towards the opening 111 of the housing along the direction X3, thereby passing through the opening 111 of the housing 11 and emitting towards an exterior of the housing 11 of the optoelectronic structure 1. Therefore, it can be known that the path of the optical signal L3 may be substantially along the direction X3 and pass through the opening 111 of the housing 11.

The optical signal L4 generated from the optical guiding element 15 may advance towards the opening 112 of the housing along the direction Z1, thereby passing through the opening 112 of the housing 11 and emitting towards an exterior of the housing 11 of the optoelectronic structure 1. Therefore, it can be known that the path of the optical signal L4 may be substantially along the direction Y4 and pass through the opening 111 of the housing 11.

Given the above, it can be known that the optoelectronic structure 1 may provide at least two optical signals in at least two different directions. Likewise, the optoelectronic structure 1 may be capable of receiving at least two optical signals, each reflected from external objects along at least two distinct directions. The external object may include a movable objects and/or an immovable objects, such as vehicle and building.

Referring to FIG. 1A and FIG. 1B, an external optical signal L5, reflected off an external object, may pass through the opening 111 of the housing 11 and enter an interior of the housing 11 along a direction X5. The optical transceiver module 12 may receive the optical signal L5 in the direction X5. In some embodiments of the present disclosure, the waveguide 1215 of the photonic component 121 is configured to receive the optical signal L5. After the optical transceiver module 12 receive the optical signal L5, the optical transceiver module 12 may transmit information related to the optical signal L5 to a processor/controller through the substrate 10. Further, an external optical signal L6, reflected off an external object, may pass through the opening 112 of the housing 11 and enter an interior of the housing 11 along a direction Z2. The optical guiding element may receive the optical signal L6 in the direction Z2 and redirect the optical signal L6 to advance toward the optical transceiver module 12. In some embodiments of the present disclosure, the waveguide 1215 of the photonic component 121 is configured to receive the optical signal L6. After the optical transceiver module 12 receive the optical signal L6, the optical transceiver module 12 may transmit information related to the optical signal L6 to the processor/controller through the substrate 10.

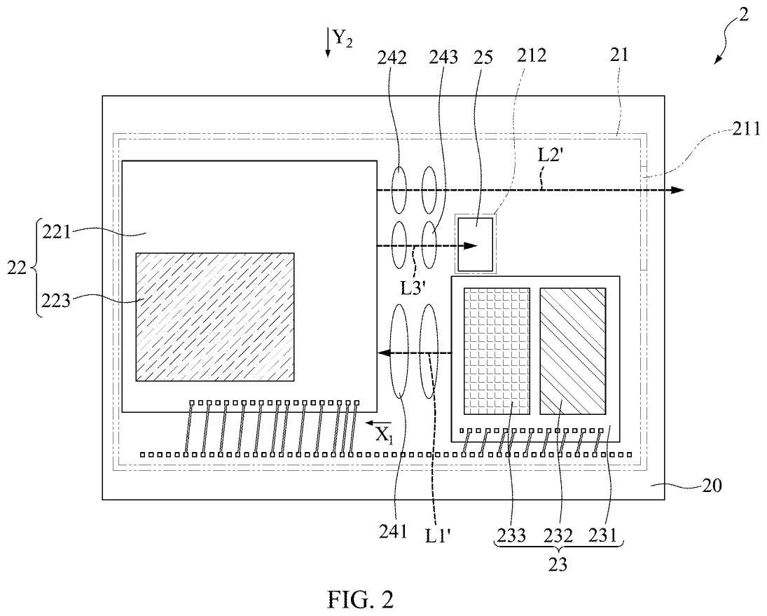

FIG. 2 is a schematic top view of an optoelectronic structure 2 in accordance with an embodiment of the instant disclosure. As shown in FIG. 2, the optoelectronic structure 2 may include a substrate 20, a housing 21, a photonic component 221, an electronic component 223, a photonic component 231, an electronic component 232 and a laser component 233. The substrate 20 is the same as, or similar to, the substrate 10 shown in FIG. 1A and FIG. 1B. The photonic component 231 may be disposed on and electrically connected to the substrate 20, and the electronic component 232 and the laser component 233 may be stacked on the photonic component 231. The photonic component 231 is the same as, or similar to, the photonic component 131 shown in FIG. 1A and FIG. 1B. The electronic component 232 is the same as, or similar to, the electronic component 132 shown in FIG. 1A and FIG. 1B. The laser component 233 is the same as, or similar to, the laser component 133 shown in FIG. 1A and FIG. 1B. The photonic component 231, the electronic component 232 and the laser component 233 may be electrically connected to each other and thus may jointly be considered as an optical emission module 23 of the optoelectronic structure 2.

The photonic component 221 may be disposed on and electrically connected to the substrate 20 and the electronic component 223 may be stacked on the photonic component 221. The photonic component 221 is similar to the photonic component 121 shown in FIG. 1A and FIG. 1i, with the distinction that the photonic component 221 may emit at least two optical signals. Moreover, the electronic component 223 is the same as, or similar to, the electronic component 123 shown in FIG. 1A and FIG. 1B. The photonic component 221 and the electronic component 223 may be electrically connected to each other and thus may jointly be considered as an optical transceiver module 22 of the optoelectronic structure 2.

The optoelectronic structure 2 may further include lens structures 241, 242 and 243 and an optical guiding element 25. The lens structure 241 may be disposed on the substrate 20 and between the photonic component 221 and the photonic component 231. That is, the lens structure 241 may be located between the optical transceiver module 22 and the optical emission module 23 of the optoelectronic structure 2. The lens structure 241 is the same as, or similar to, the lens structure 141 shown in FIG. 1A and FIG. 1B. The lens structures 242 and 243 may be disposed on the substrate 20. The lens structure 242 is the same as, or similar to, the lens structure 142 shown in FIG. 1A and FIG. 1B. The lens structure 242 is configured to allow one of the at least two optical signals emitted from the photonic component 221 to pass through. Moreover, the lens structure 243 is the same as, or similar to, the lens structure 142 shown in FIG. 1A and FIG. 1B. The lens structure 243 is configured to allow another one of the at least two optical signals emitted from the photonic component 221 to pass through. In addition, the optical guiding element 25 may be disposed on the substrate 20 and substantially aligned with the lens structure 243. In some embodiments of the present disclosure, the optical guiding element 25 includes a reflective element. That is, the optical guiding element 25 may be used to change the direction of an incoming light beam.

The housing 21 may be disposed on the substrate and cover the photonic component 221, the electronic component 223, the photonic component 231, the electronic component 232, the laser component 233, the lens structures 241, 242 and 243 and the optical guiding element 25. The housing 21 is the same as, or similar to, the housing 11 shown in FIG. 1A and FIG. 1B. That is, the housing 21 is configured to protect the optical transceiver module 22 and the optical emission module 23. The housing 21 may include an opening 211 at its lateral side and an opening 212 at its upper side. As shown in FIG. 2, the opening 211 may be substantially aligned with the lens structure 242 in a horizontal direction, and the opening 212 may be substantially aligned with the optical guiding element 25 in a vertical direction.

Referring to FIG. 2, the optical emission module 23 with the photonic component 231, the electronic component 232 and the laser component 233 may emit an optical signal L1′ to the optical transceiver module 22 with the photonic component 221 and the electronic component 223. The optical signal L1′ may pass through the lens structure 241. After the optical transceiver module 22 receives the optical signal L1′ emitted from the optical emission module 23, the optical transceiver module 22 may emit optical signals L2′ and L3′. The optical signal L2′ may pass through the lens structure 242 and advance toward the opening 211 of the housing, thereby passing through the opening 211 of the housing 21 and emitting towards an exterior of the housing 21 of the optoelectronic structure 2. The optical signal L3′ may pass through the lens structure 243 and be redirected towards the opening 212 by the reflection from the optical guiding element 25, thereby passing through the opening 212 of the housing 21 and emitting towards an exterior of the housing 21 of the optoelectronic structure 2.

As shown in FIG. 2, a path of the optical signal L3′ may overlap a path of the optical signal L2′ and/or a path of the optical signal L1′ in a direction Y2, which may be substantially perpendicular to the path of the optical signal L1′, L2′ or L3′. Further, the path of the optical signal L3′ may be substantially parallel to the path of the optical signal L1′ and/or the path of the optical signal L2′. Moreover, as abovementioned, the optical signal L3′ may be redirected towards the opening 212 by the reflection from the optical guiding element 25, and thus a path of the optical signal L3′ toward the opening 212 may be substantially perpendicular to the path of the optical signal L3′ toward the optical guiding element 25.

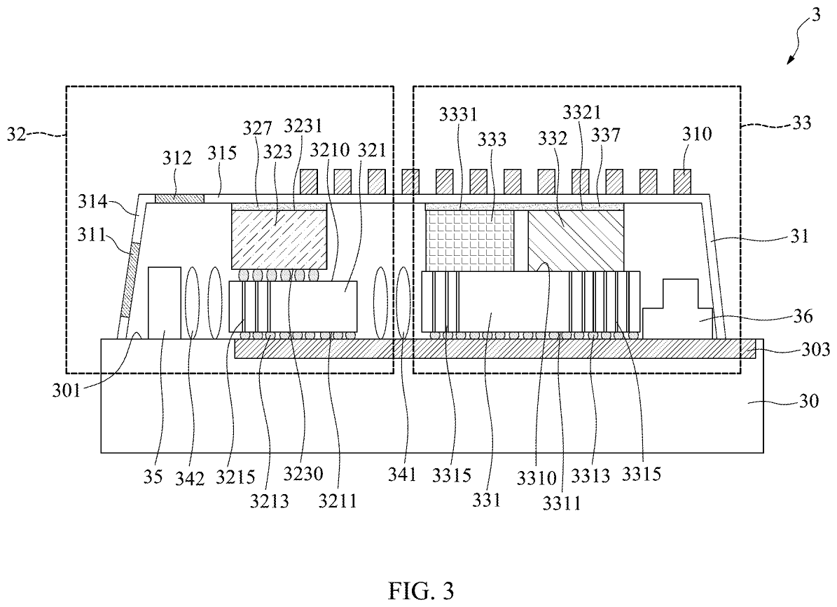

FIG. 3 is a schematic cross-sectional view of an optoelectronic structure 3 in accordance with an embodiment of the instant disclosure. As shown in FIG. 3, the optoelectronic structure 3 may include a substrate 30, a photonic component 321, an electronic component 323, a photonic component 331, an electronic component 332 and a laser component 333. The substrate 30 may be or include a carrier. The substrate 30 may be composed of a silicon-based material, leveraging the well-established properties of silicon to enhance the device's performance and integration capabilities. Silicon-based substrates are chosen for their excellent electrical, thermal, and mechanical properties, making them ideal for a wide range of applications. The substrate 30 may include an interconnection structure, which may include such as a plurality of conductive traces and/or a plurality of conductive vias. The interconnection structure may include a redistribution layer (RDL) 303. The redistribution layer 303 may be disposed on an upper surface 301 of the substrate 30.

Referring to FIG. 3, the photonic component 321 may be disposed over the substrate 30 and the electronic component 323 may be stacked on the photonic component 321. In some embodiments of the present disclosure, the photonic component 321 includes photonic integrated circuits (PIC). The photonic integrated circuits may be used for emitting laser pulses, guiding the optical path, and receiving the light reflected back. Moreover, the PIC of the photonic component 321 may include a waveguide (not shown). The waveguide is configured to direct light waves from one point to another within the chip. By precisely controlling the shape and material properties of the waveguides, light's propagation path can be effectively managed, facilitating functions such as routing, splitting, combining, and modulating optical signals. As shown in FIG. 3, the photonic component 321 may include a surface 3211 (e.g., a lower surface) facing the substrate 30 and a surface 3210 (e.g., an upper surface) opposite to the surface 3211. Further, the surface 3211 may include an active surface of the photonic component 321. A plurality of electrical connections 3213 may be disposed between the surface 3211 of the photonic component 321 and the upper surface 301 of the substrate 30 and configured to electrically connect the active surface of the photonic component 321 to the redistribution layer 303 of the substrate 30. That is, the photonic component 321 and the substrate 30 may be electrically connected to each other. In some embodiments of the present disclosure, the electrical connection 3213 includes a micro-bump. Moreover, the photonic component 321 may include a plurality of conductive vias 3215 passing through it. The conductive vias 3215 may be electrically connected to the electrical connections 3213. In some embodiments of the present disclosure, the conductive via 3215 includes a through silicon via (TSV).

In some embodiments of the present disclosure, the electronic component 323 includes electronic integrated circuits (EIC). The electronic integrated circuits may be used for processing signals from photodetectors, including signal amplification, filtering, analog-to-digital conversion (converting analog signals to digital signals), and performing initial data processing. As shown in FIG. 3, the electronic component 323 may include a surface 3230 (e.g., a lower surface) facing the surface 3210 of the photonic component 321 and a surface 3231 (e.g., an upper surface) opposite to the surface 3210. Further, the surface 3230 may include an active surface of the electronic component 323. Moreover, a plurality of electrical connections 326 is arranged between the surface 3230 of the electronic component 323 and the surface 3210 of the photonic component 321 and configured to electrically connect the active surface of the electronic component 323 to the conductive vias 3215 of the photonic component 321. That is, the electronic component 323 and the photonic component 321 may be electrically connected to each other. In some embodiments of the present disclosure, the electrical connection 326 includes a micro-bump.

The photonic component 321 and the electronic component 323 may jointly be considered as an optical transceiver module 32. The optical transceiver module 32 may be electrically connected to the substrate 30.

The photonic component 331 may be disposed over the substrate 30 and the electronic component 332 and the laser component 333 may be stacked on the photonic component 331. In some embodiments of the present disclosure, the photonic component 331 includes photonic integrated circuits (PIC). The photonic integrated circuits may be used for emitting laser pulses, guiding the optical path, and receiving the light reflected back. Moreover, the PIC of the photonic component 331 may include a waveguide (not shown). The waveguide is configured to direct light waves from one point to another within the chip. By precisely controlling the shape and material properties of the waveguides, light's propagation path can be effectively managed, facilitating functions such as routing, splitting, combining, and modulating optical signals. As shown in FIG. 3, the photonic component 331 may include a surface 3311 (e.g., a lower surface) facing the substrate and a surface 3310 (e.g., an upper surface) opposite to the surface 3311. Further, the surface 3311 may include an active surface of the photonic component 331. A plurality of electrical connections 3313 may be disposed between the surface 3311 of the photonic component 331 and the upper surface 301 of the substrate 30 and configured to electrically connect the active surface of the photonic component 331 to the redistribution layer 303 of the substrate 30. That is, the photonic component 331 and the substrate 30 may be electrically connected to each other. In some embodiments of the present disclosure, the electrical connection 3313 includes a micro-bump. Moreover, the photonic component 331 may include a plurality of conductive vias 3315 passing through it. The conductive vias 3315 may be electrically connected to the electrical connections 3313. In some embodiments of the present disclosure, the conductive via 3315 includes a through silicon via (TSV).

In some embodiments of the present disclosure, the electronic component 332 includes electronic integrated circuits (EIC). The electronic integrated circuits may be used for processing signals from photodetectors, including signal amplification, filtering, analog-to-digital conversion (converting analog signals to digital signals), and performing initial data processing. As shown in FIG. 3, the electronic component 332 may include a surface 3320 (e.g., a lower surface) facing the surface 3310 of the photonic component 331 and a surface 3321 (e.g., an upper surface) opposite to the surface 3320. Further, the surface 3320 may include an active surface of the electronic component 332. The surface 3320 of the electronic component 332 may be in abutment with the surface 3310 of the photonic component 331, and thus the active surface of the electronic component 332 may be electrically connected to the conductive vias 3315 of the photonic component 331.

The laser component 333 may include a distributed feedback laser. The distributed feedback laser may be used for emitting highly coherent and wavelength-precise light beams. As shown in FIG. 3, the laser component 333 may include a surface 3330 (e.g., a lower surface) facing the surface 3310 of the photonic component 331 and a surface 3331 (e.g., an upper surface) opposite to the surface 3330. Further, the surface 3330 may include an active surface of the laser component 333. The surface 3330 of the laser component 333 may be in abutment with the surface 3310 of the photonic component 331, and thus the active surface of the laser component 333 may be electrically connected to the conductive vias 3315 of the photonic component 331.

The photonic component 331, the electronic component 332 and the laser component 333 may jointly be considered as an optical emission module 33. The optical emission module 33 may be electrically connected to the substrate 30. Moreover, the optical transceiver module 32 and the optical emission module 33 may be electrically coupled to each other through the substrate 30.

As shown in FIG. 3, the optoelectronic structure 3 may further include lens structures 341 and 342 and an optical guiding element 35. The lens structure 341 may be disposed between the optical transceiver module 32 and the optical emission module 33. In some embodiments of the present disclosure, the lens structure 341 includes a plurality of lenses. In some embodiments of the present disclosure, the lens structure 341 is configured to collimate the optical signal from a divergent light into a collimated or parallel light beam having a consistent beam size. Moreover, the lens structure 342 is disposed between the optical transceiver module 32 and the optical guiding element 35. In some embodiments of the present disclosure, the lens structure 342 includes a plurality of lenses. In some embodiments of the present disclosure, the lens structure 342 is configured to collimate the optical signal from a divergent light into a collimated or parallel light beam having a consistent beam size. In some embodiments of the present disclosure, the optical guiding element 35 includes a beam splitter which is used to divide an incoming light beam into two parts. In some embodiments of the present disclosure, the optical guiding element 35 includes a reflective element, which is used to change the direction of an incoming light beam.

In some embodiments of the present disclosure, the optoelectronic structure 3 may further include an electronic component 36 disposed on the substrate 30. In some embodiments of the present disclosure, the electronic component 36 includes an integrated passive device (IPD).

Further, referring to FIG. 3, the optoelectronic structure 3 may include a housing 31. The housing 31 may be disposed on the upper surface 301 of the substrate 30. The housing 31 may cover the optical transceiver module 32 (which may include the photonic component 321 and the electronic component 323), the optical emission module 33 (which may include the photonic component 331, the electronic component 332 and the laser component 333), the lens structures 341 and 342 and the optical guiding element 35. That is, the housing 31 is configured to protect the optical transceiver module 32 and the optical emission module 33. The housing 31 may include a lateral portion 314 and an upper portion 315 adjacent to the lateral portion 314. In some embodiments of the lateral portion 314 is located at a lateral side of the housing 31. That is, the lateral portion 314 of the housing 31 may be in abutment with the upper surface 301 of the substrate 30. In some embodiments of the present disclosure, the upper portion 315 is located at an upper side of the housing 31. That is, the upper portion 315 may be spaced apart from the upper surface 301 of the substrate 30. The lateral portion 314 of the housing 31 may include an opening 311. As shown in FIG. 3, the opening 311 may be substantially align with the optical guiding element 35 in a direction which may be substantially parallel to the upper surface 301 of the substrate 30. The upper portion 315 of the housing 31 may include an opening 312. As shown in FIG. 3, the opening 312 may be disposed directly above the optical guiding element 35 and substantially aligned with the optical guiding element 35 in a direction which may be substantially perpendicular to the upper surface 301 of the substrate 30.

As shown in FIG. 3, the housing 31 may include a heat sink 310 at its upper side. In some embodiments of the present disclosure, the housing 31 may include a thermal conductive material. The electronic component 323 may be connected to the upper side of the housing 31. The surface 3231 of the electronic component 323 may be attached to the upper side of the housing 31 through a thermal interface material (TIM) 327. In some embodiments of the present disclosure, the thermal interface material 327 includes a thermal paste. That is, the housing 31 with the heat sink 310 and the thermal interface material 327 may provide a thermal dissipation path for the optical transceiver module 32. Moreover, the electronic component 332 and the laser component 333 may be connected to the upper side of the housing 31. The surface 3321 of the electronic component 332 and the surface 3331 of the laser component 333 may be attached to the upper side of the housing 31 through a thermal interface material 337. In some embodiments of the present disclosure, the thermal interface material 337 includes a thermal paste. That is, the housing 31 with the heat sink 310 and the thermal interface material 337 may provide a thermal dissipation path for the optical emission module 33. In addition, because the upper surfaces of the electronic component 323, the electronic component 332 and the laser component 333 may be all attached to the upper side of the housing 31, it can be understood that the upper surfaces of the electronic component 323, the electronic component 332 and the laser component 333 may be substantially coplanar with each other.

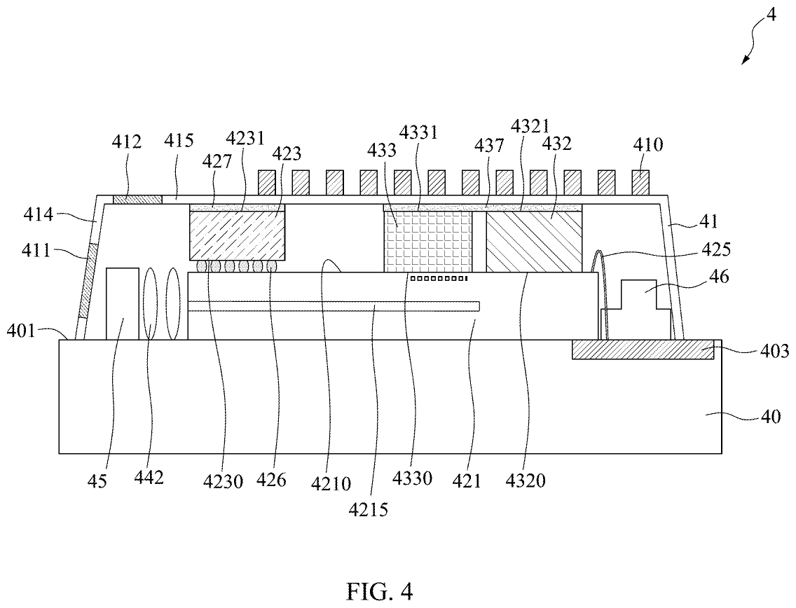

FIG. 4 is a schematic cross-sectional view of an optoelectronic structure 4 in accordance with an embodiment of the instant disclosure. As shown in FIG. 4, the optoelectronic structure 4 may include a substrate 40, a photonic component 421, an electronic component 423, an electronic component 432 and a laser component 433. The substrate 40 may be or include a carrier. The substrate 40 may be composed of a silicon-based material, leveraging the well-established properties of silicon to enhance the device's performance and integration capabilities. Silicon-based substrates are chosen for their excellent electrical, thermal, and mechanical properties, making them ideal for a wide range of applications. The substrate 40 may include an interconnection structure, which may include such as a plurality of conductive traces and/or a plurality of conductive vias. The interconnection structure may include a redistribution layer (RDL) 403. The redistribution layer 403 may be disposed on an upper surface 401 of the substrate 40.

Referring to FIG. 4, the photonic component 421 may be disposed over the substrate 40 and the electronic component 423, the electronic component 432 and the laser component 433 may be stacked on the photonic component 421. In some embodiments of the present disclosure, the photonic component 421 includes photonic integrated circuits (PIC). The photonic integrated circuits may be used for emitting laser pulses, guiding the optical path, and receiving the light reflected back. Moreover, the PIC of the photonic component 421 may include a waveguide 4215. The waveguide 4215 is configured to direct light waves from one point to another within the chip. By precisely controlling the shape and material properties of the waveguides, light's propagation path can be effectively managed, facilitating functions such as routing, splitting, combining, and modulating optical signals. In some embodiments of the present disclosure, the photonic component 421 may integrates the photonic component 121 and the photonic component 131 as shown in FIG. 1A and FIG. 1B. That is, the photonic component 421 may include the photonic component 121 and the photonic component 131. As shown in FIG. 4, the photonic component 421 may include a surface 4210 (e.g., an upper surface) facing away from the substrate 10. Further, the surface 4210 may include an active surface of the photonic component 421. Moreover, an electrical connection 425 may electrically connect the surface 4210 (with the active surface) of the photonic component 421 to the redistribution layer 403 of the substrate 40. Thus, the photonic component 421 may be electrically connected to the substrate 40 through the electrical connection 425. In some embodiments of the present disclosure, the electrical connection 425 includes a conductive wire. Since the photonic component 421 may integrates may integrate at least two photonic components, such as the photonic component 121 and the photonic component 131 as shown in FIG. 1A and FIG. 1B, the risk of optical misalignment in the assembly of optoelectronic structure 4 could be reduced.

The electronic component 423 may include electronic integrated circuits (EIC). The electronic integrated circuits may be used for processing signals from photodetectors, including signal amplification, filtering, analog-to-digital conversion (converting analog signals to digital signals), and performing initial data processing. As shown in FIG. 4, the electronic component 123 may include a surface 4230 (e.g., a lower surface) facing the surface 4210 of the photonic component 421 and a surface 4231 (e.g., a lower surface) opposite to the surface 4230. Further, the surface 4230 may include an active surface of the electronic component 423. That is, the active surface of the photonic component 421 may face the active surface of the electronic component 423. Moreover, a plurality of electrical connections 426 may be arranged between the surface 4210 of the photonic component 421 and the surface 4230 of the electronic component 423 and configured to electrically connect the active surface of the electronic component 423 to the active surface of the photonic component 421. Thus, the photonic component 421 and the electronic component 423 may be electrically connected to each other through the electrical connections 426. In some embodiments of the present disclosure, the electrical connection 426 includes a micro-bump.

The electronic component 432 may include electronic integrated circuits (EIC). The electronic integrated circuits may be used for processing signals from photodetectors, including signal amplification, filtering, analog-to-digital conversion (converting analog signals to digital signals), and performing initial data processing. As shown in FIG. 4, the electronic component 423 may include a surface 4320 (e.g., a lower surface) facing the surface 4210 of the photonic component 421 and a surface 4321 (e.g., an upper surface) opposite to the surface 4320. Further, the surface 4320 may include an active surface of the electronic component 432. That is, the active surface of the photonic component 421 may face the active surface of the electronic component 432. The surface 4210 of the photonic component 421 may be in abutment with the surface 4320 of the electronic component 432. Thus, the photonic component 421 and the electronic component 432 may be configured in a chip-to-chip assembly and electrically connected to each other.

The laser component 433 may include a distributed feedback laser. The distributed feedback laser may be used for emitting highly coherent and wavelength-precise light beams. As shown in FIG. 4, the laser component 133 may include a surface 4330 (e.g., a lower surface) facing the surface 4210 of the photonic component 421 and a surface 4331(e.g., an upper surface) opposite to the surface 4330. Further, the surface 4330 may include an active surface of the laser component 433. That is, the active surface of the photonic component 421 may face the active surface of the laser component 433. The surface 4210 of the photonic component 421 may be in abutment with the surface 4330 of the laser component 433. Thus, the photonic component 421 and the laser component 433 may be configured in a chip-to-chip assembly and electrically connected to each other.

As shown in FIG. 4, the optoelectronic structure 4 may further include lens structure 442 and an optical guiding element 45. The lens structure 442 is disposed between the optical transceiver module 42 and the optical guiding element 45. In some embodiments of the present disclosure, the lens structure 442 includes a plurality of lenses. In some embodiments of the present disclosure, the lens structure 442 is configured to collimate the optical signal from a divergent light into a collimated or parallel light beam having a consistent beam size. In some embodiments of the present disclosure, the optical guiding element 45 includes a beam splitter which is used to divide an incoming light beam into two parts. In some embodiments of the present disclosure, the optical guiding element 45 includes a reflective element, which is used to change the direction of an incoming light beam.

In some embodiments of the present disclosure, the optoelectronic structure 4 may further include an electronic component 46 disposed on the substrate 30. In some embodiments of the present disclosure, the electronic component 46 includes an integrated passive device (IPD).

Further, referring to FIG. 4, the optoelectronic structure 4 may include a housing 41. The housing 41 may be disposed on the upper surface 401 of the substrate 40. The housing 41 may cover the photonic component 421, the electronic component 423, the electronic component 432 and the laser component 433, the lens structure 442 and the optical guiding element 45. That is, the housing 41 is configured to protect the optical transceiver module 42 and the optical emission module 43. The housing 41 may include a lateral portion 414 and an upper portion 415 adjacent to the lateral portion 414. In some embodiments of the lateral portion 414 is located at a lateral side of the housing 41. That is, the lateral portion 414 of the housing 41 may be in abutment with the upper surface 401 of the substrate 40. In some embodiments of the present disclosure, the upper portion 415 is located at an upper side of the housing 41. That is, the upper portion 415 may be spaced apart from the upper surface 401 of the substrate 40. The lateral portion 414 of the housing 41 may include an opening 411. As shown in FIG. 4, the opening 411 may be substantially align with the optical guiding element 45 in a direction which may be substantially parallel to the upper surface 401 of the substrate 40. The upper portion 415 of the housing 41 may include an opening 412. As shown in FIG. 4, the opening 412 may be disposed directly above the optical guiding element 45 and substantially aligned with the optical guiding element 45 in a direction which may be substantially perpendicular to the upper surface 401 of the substrate 40.

As shown in FIG. 4, the housing 41 may include a heat sink 410 at its upper side. In some embodiments of the present disclosure, the housing 41 may include a thermal conductive material. The electronic component 423 may be connected to the upper side of the housing 41. The surface 4231 of the electronic component 423 may be attached to the upper side of the housing 41 through a thermal interface material (TIM) 427. In some embodiments of the present disclosure, the thermal interface material 427 includes a thermal paste. That is, the housing 41 with the heat sink 410 and the thermal interface material 427 may provide a thermal dissipation path for the optical transceiver module 42. Moreover, the electronic component 432 and the laser component 433 may be connected to the upper side of the housing 41. The surface 4321 of the electronic component 432 and the surface 4331 of the laser component 433 may be attached to the upper side of the housing 41 through a thermal interface material (TIM) 437. In some embodiments of the present disclosure, the thermal interface material includes thermal paste. That is, the housing 41 with the heat sink 410 and the thermal interface material 437 may provide a thermal dissipation path for the optical emission module 43. In addition, because the upper surfaces of the electronic component 423, the electronic component 432 and the laser component 433 may be all attached to the upper side of the housing 41, it can be understood that the upper surfaces of the electronic component 423, the electronic component 432 and the laser component 433 may be substantially coplanar with each other.

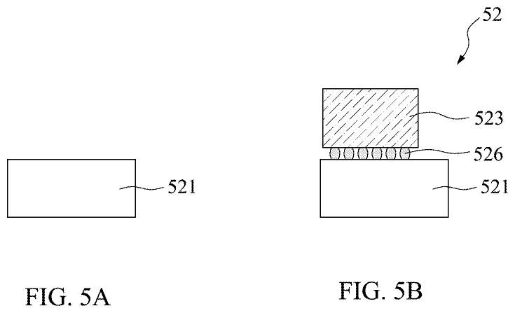

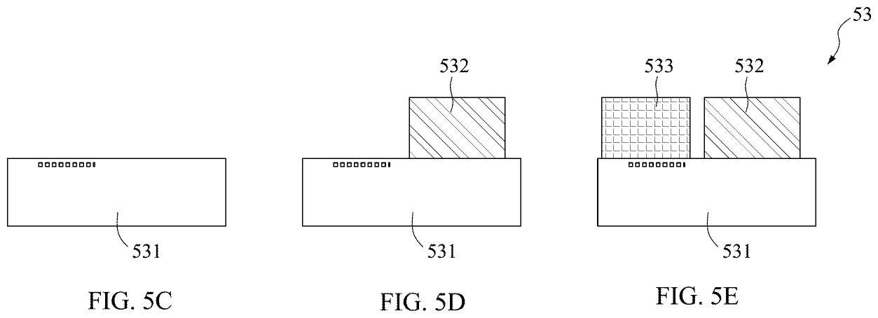

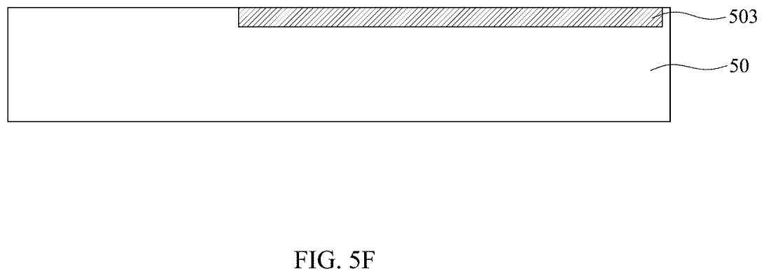

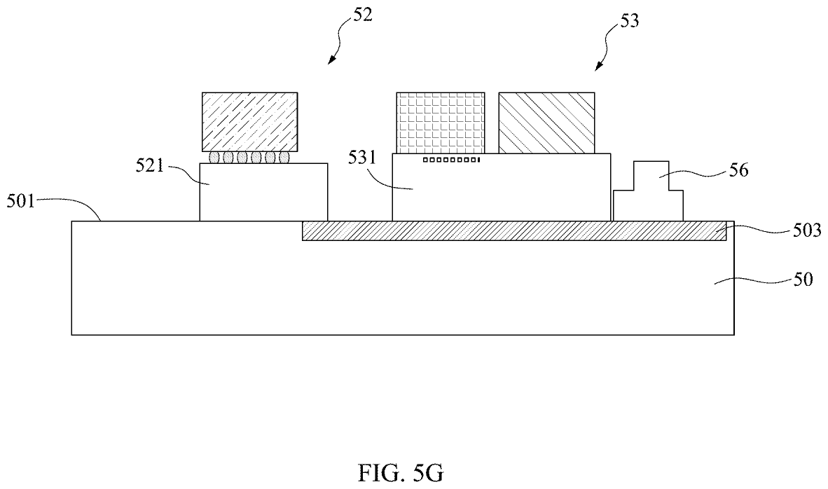

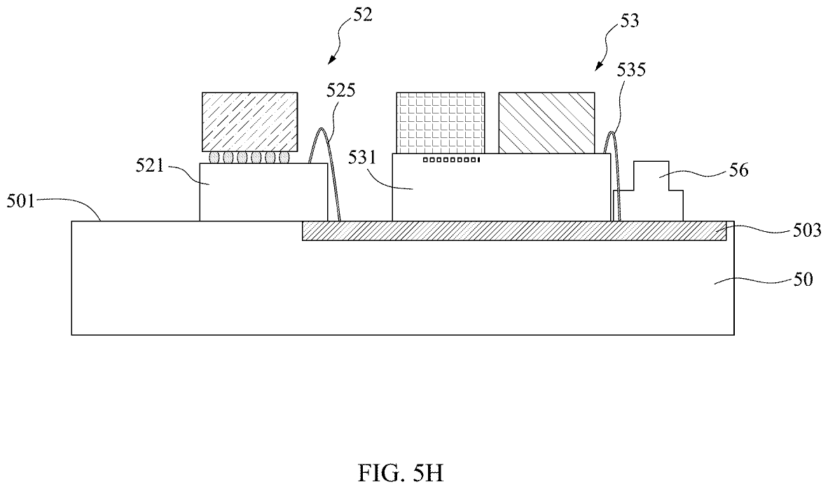

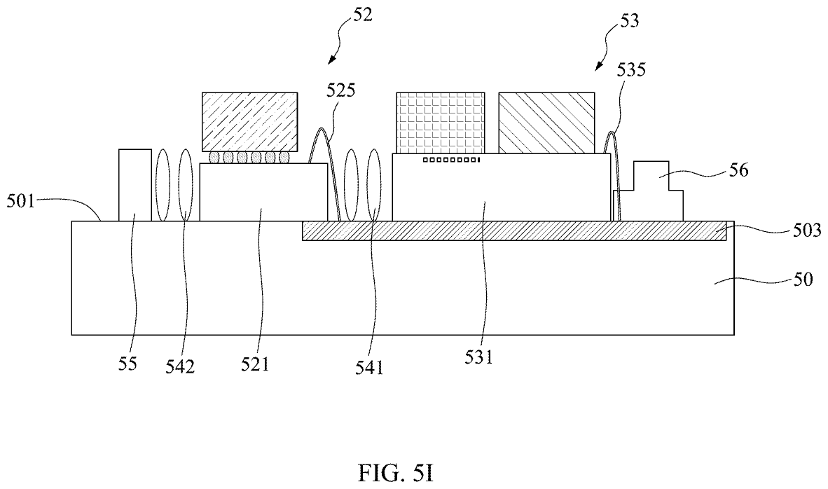

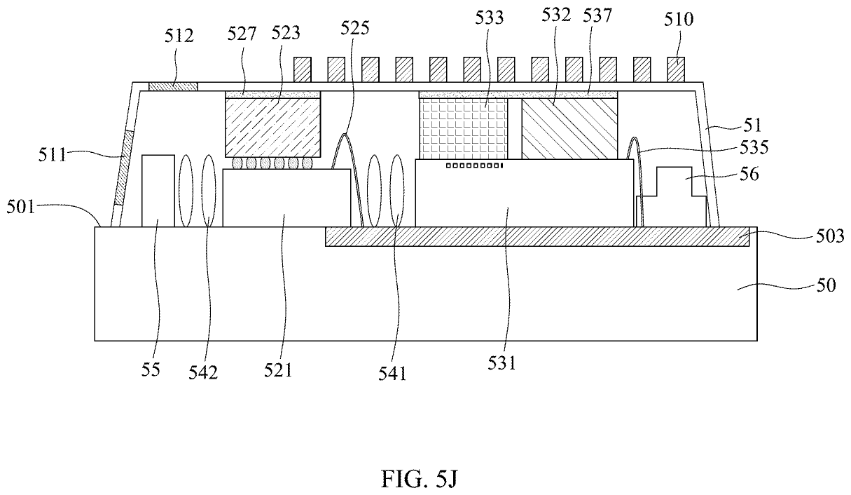

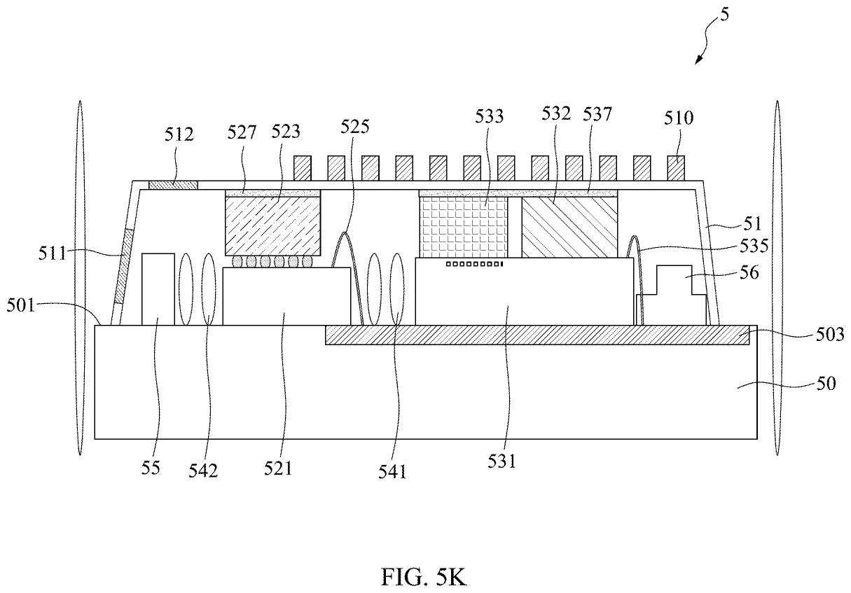

FIG. 5A, FIG. 5B, FIG. 5C, FIG. 5D, FIG. 5E, FIG. 5F, FIG. 5G, FIG. 5H, FIG. 5I, FIG. 5J and FIG. 5K illustrate one or more stages of an example of a method for manufacturing an optoelectronic structure in accordance with some embodiments of the present disclosure.

Referring to FIG. 5A, a photonic component 521 is provided. In some embodiments of the present disclosure, the photonic component 521 includes photonic integrated circuits (PIC).

Referring to FIG. 5B, an electronic component 523 is provided. In some embodiments of the present disclosure, the electronic component 523 includes electronic integrated circuits (EIC). The electronic component 523 may be mounted on the photonic component 521 and electrically connected to the photonic component 521 through electrical connections 526.

The photonic component 521 and the electronic component 523 may jointly be an optical transceiver module 52.

Referring to FIG. 5C, a photonic component 531 is provided. In some embodiments of the present disclosure, the photonic component 531 includes photonic integrated circuits (PIC).

Referring to FIG. 5D, an electronic component 532 is provided. In some embodiments of the present disclosure, the electronic component 532 includes electronic integrated circuits (EIC). The electronic component 532 may be mounted on the photonic component 531. The photonic component 531 and the electronic component 532 may be configured in a chip-to-chip assembly and electrically connected to each other.

Referring to FIG. 5E, a laser component 533 is provided. In some embodiments of the present disclosure, the laser component 533 includes a distributed feedback laser. The laser component 533 may be mounted on the photonic component 531. The photonic component 531 and the laser component 533 may be configured in a chip-to-chip assembly and electrically connected to each other.

The photonic component 531, the electronic component 532 and the laser component 533 may jointly be an optical emission module 53.

Referring to FIG. 5F, a substrate 50 is provided. The substrate 50 may be composed of a silicon-based material. The substrate 50 may include a redistribution layer 503.

Referring to FIG. 5G, the optical transceiver module 52 and the optical emission module 53 are attached to an upper surface 501 of the substrate 50. Moreover, an electronic component 56 is mounted to the substrate 50. In some embodiments of the present disclosure, the electronic component 56 includes an integrated passive device (IPD).

Referring to FIG. 5H, electrical connections 525 and 535 are provided. The electrical connection 525 may connect the photonic component 521 of the optical transceiver module 52 to the substrate 50 and serve to establish electrical connectivity between the optical transceiver module 52 and the substrate 50. The electrical connection 535 may connect the photonic component 531 of the optical emission module 53 to the substrate 50 and serve to establish electrical connectivity between the optical emission module 53 and the substrate 50.

Referring to FIG. 5I, lens structures 541 and 542 and an optical guiding element 55 are provided. The lens structures 541 and 542 and an optical guiding element 55 may be attached to the upper surface 501 of the substrate 50. In some embodiments of the present disclosure, the lens structure 541, 542 includes a plurality of lenses. In some embodiments of the present disclosure, the lens structure 541, 542 is configured to collimate the optical signal from a divergent light into a collimated or parallel light beam having a consistent beam size. In some embodiments of the present disclosure, the optical guiding element 55 includes a beam splitter which is used to divide an incoming light beam into two parts. In some embodiments of the present disclosure, the optical guiding element 55 includes a reflective element, which is used to change the direction of an incoming light beam.

Referring to FIG. 5J, a housing 51 is provided. The housing 51 may be attached to the upper surface 501 of the substrate 50. The housing 51 may include an opening 511, which is located at a lateral side of the housing 51 and substantially aligned with the optical guiding element 55 in a horizontal direction, and an opening 512, which is located at an upper side of the housing 51 and substantially aligned with the optical guiding element 55 in a vertical direction. Moreover, the electronic component 523 may be attached to the housing 51 through the thermal interface material 527, and the electronic component 532 and the laser component 533 may be attached to the housing 51 through the thermal interface material 537.

Referring to FIG. 5K, a singulation process is performed by cutting through the substrate 50. The singulation may be performed, for example, by using a dicing saw, laser or other appropriate cutting technique.

After the manufacturing process as shown in FIG. 5A, FIG. 5B, FIG. 5C, FIG. 5D, FIG. 5E, FIG. 5F, FIG. 5G, FIG. 5H, FIG. 5I, FIG. 5J and FIG. 5K, the optoelectronic structure 5 is formed (see FIG. 5K). In some embodiments of the present disclosure, the optoelectronic structure 5 is the same as, or similar to, the optoelectronic structure 1 shown in FIG. 1A and FIG. 1B.

The present disclosure relates an optoelectronic structure that stacks an electronic component with an Electronic Integrated Circuit (EIC) and a photonic component with a Photonic Integrated Circuit (PIC). This configuration forms an optical transceiver module and an optical emission module, which are then assembled separately onto a carrier. This assembly method effectively minimizes optical alignment challenges and reduces manufacturing risks by simplifying the integration process of the optical components, thereby enhancing the efficiency and reliability of the optoelectronic structure in applications requiring precise optical and electronic integration.

Furthermore, the optoelectronic structure may accommodate optical elements like lenses and reflective mirrors within its housing, enabling the emission of at least two light beams in distinct directions. This capability allows the structure to perform LiDAR scanning across different orientations, enhancing its ability to detect and measure the distance to objects in its environment with greater accuracy and efficiency. The inclusion of such optical components within a single housing simplifies the system's design while expanding its functional versatility in LiDAR applications.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein are described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations on the present disclosure.

What is claimed is:

1. An optoelectronic structure, comprising:
an optical device; and
a housing covering the optical device;
wherein the optical device is configured to transmit at least one optical signal to an outside of the housing in different directions.

2. The optoelectronic structure of claim 1, wherein the at least one optical signals comprises a first optical signal and a second optical signal, wherein the housing comprises a first opening and a second opening, and wherein the first opening is located at an upper portion of the housing and configured to allow the first optical signal to pass through and the second opening is located at lateral portion of the housing and configured to allow the second signal to pass through.

3. The optoelectronic structure of claim 2, further comprising an optical element covered by the housing and disposed below the first opening, and wherein the optical element is configured to alter a path of the at least one optical signal.

4. The optoelectronic structure of claim 3, further comprising a lens structure disposed between the optical element and the optical device.

5. The optoelectronic structure of claim 1, further comprising a carrier supporting the housing and electrically connected to the optical device.

6. The optoelectronic structure of claim 1, wherein the optical device is configured to receive an optical signal reflected from an external object external to the optoelectronic structure.

7. An optoelectronic structure, comprising:
an optical emission module; and
an optical transceiver module configured to optically couple to the optical emission module and configured to emit a first optical signal along a first path adjacent the optical transceiver module.

8. The optoelectronic structure of claim 7, wherein the first optical signal is emitted in a first direction, the optical emission module is configured to emit a second optical signal in a second direction opposite to the first direction.

9. The optoelectronic structure of claim 8, wherein the optical transceiver module is configured to receive the second optical signal from a lateral side of the optical transceiver module and is configured to emit the second optical signal from the lateral side.

10. The optoelectronic structure of claim 8, further comprising a first optical element configured to guide the first optical signal into a first beam emitted in a third direction and a second beam in a fourth direction different from the third direction.

11. The optoelectronic structure of claim 10, wherein the first direction is substantially equal to the third direction.

12. The optoelectronic structure of claim 10, wherein the third direction and the fourth direction are substantially orthogonal to each other.

13. An optoelectronic structure, comprising:
a housing having a first opening and a second opening; and
an optical device covered by the housing;
wherein the optical device is configured to emit and/or receive a light passing through the first opening of the housing and configured to emit and/or receive another light passing through the second opening of the housing.

14. The optoelectronic structure of claim 13, wherein the housing has a first side portion and a second side portion different from the first side portion, and wherein the first opening is located at the first side portion and the second opening is located at the second side portion.

15. The optoelectronic structure of claim 14, wherein the first side portion is adjacent to the second side portion.

16. The optoelectronic structure of claim 14, further comprising a carrier disposed below the housing, wherein the first side portion of the housing connects an upper surface of the carrier and the second side portion of the housing is spaced apart from the upper surface of the housing.

17. The optoelectronic structure of claim 16, wherein the optical device comprises an optical emission module and an optical transceiver module disposed over the carrier respectively, and wherein the optical emission module and the optical transceiver module collectively supports the housing.

18. The optoelectronic structure of claim 17, wherein the optical transceiver module comprises a photonic component connected to the carrier and an electronic component disposed over the photonic component, and wherein the electronic component is electrically connected to the carrier through the photonic component.

19. The optoelectronic structure of claim 13, further comprising a first optical element disposed between the housing and the optical device, wherein the first optical element is configured to guide a first light beam toward the first opening.

20. The optoelectronic structure of claim 19, further comprising a second optical element disposed between the housing and the optical device, wherein the second optical element is configured to guide a second light beam toward the second opening.
